(19) United States
(12) Patent Application Publication
(10) Pub. No.: US 2020/0411712 A1
(43) Pub. Date: Dec. 31, 2020

(54) METHOD AND APPARATUS FOR PROCESSING A SOLAR CELL STRUCTURE

(71) Applicant: APPLIED MATERIALS ITALIA S.R.L., San Biagio di Callalta (IT)

(72) Inventors: Marco GALIAZZO, Quinto Di Treviso (IT); Luigi DE SANTI, Spresiano (tv) (IT); Daniele GISLON, Venice (IT); Diego TONINI, Treviso (IT); Giorgio CELLERE, Torri di Quartesolo (IT)

(21) Appl. No.: 16/979,115

(22) PCT Filed: Feb. 8, 2018
(86) PCT No.: PCT/EP2018/055792

§ 371 Date: Sep. 8, 2020

(51) Int. Cl. H01L 31/18

(52) U.S. Cl. CPC H01L 31/1876; H01L 31/186

(57) ABSTRACT

A method for processing a solar cell structure includes providing a solar cell structure (10) having a first side (12) and a second side (14). The method includes at least one of (a) scribing the solar cell structure on the first side of the solar cell structure and (b) cutting through the solar cell structure using a laser beam incident on the first side of the solar cell structure. The method includes providing an adhesive (32) on the second side of the solar cell structure.

### FIELD

Embodiments of the present disclosure relate to a method and an apparatus for processing a solar cell structure. More specifically, embodiments described herein relate to a method and an apparatus for manufacturing a shingled solar cell arrangement including a string of overlapping solar cell pieces.

### BACKGROUND

Solar cells are photovoltaic devices that convert sunlight directly into electrical power. The efficiency of the solar cells can be affected by an active area on a front surface of the solar cell which is exposed to light for converting sunlight into electrical power. The active area can be reduced due to the presence of electrical contacts, such as fingers and/or bus bars, on the front surface of the solar cells. The presence of the electrical contacts on the front surface of the solar cells can thus reduce a module power of a solar cell module including the solar cells.

Shingled solar cell arrangements can increase an output power of a solar cell module. The increase in the output power can be affected by a quality of a manufacturing process, such as a quality of the elements used to assemble the shingled solar cell arrangement. Further, a proper assembling of the shingled solar cell arrangement can be cumbersome, and a throughput and/or yield can be low.

In view of the above, new methods and apparatuses for processing solar cells for the manufacture of shingled solar cell arrangements that overcome at least some of the problems in the art are beneficial. The present disclosure particularly aims at improving the manufacturing process of solar cell arrangements, such as shingled solar cells.

### SUMMARY

According to an embodiment, a method for processing a solar cell structure is provided. The method includes providing a solar cell structure having a first side and a second side. The method includes at least one of (a) scribing the solar cell structure on the first side of the solar cell structure and (b) cutting through the solar cell structure using a laser beam incident on the first side of the solar cell structure. The method includes providing an adhesive on the second side of the solar cell structure.

According to a further embodiment, an apparatus for processing a solar cell structure is provided. The solar cell structure has a first side and a second side. The apparatus includes: a support system including one or more support units for supporting a solar cell structure; a laser unit configured for at least one of scribing the solar cell structure supported by the support system and cutting through the solar cell structure supported by the support system; and an adhesive application unit configured for providing an adhesive on the solar cell structure supported by the support system. The apparatus is configured for at least one of (a) scribing the solar cell structure on the first side of the solar cell structure and (b) cutting through the solar cell structure using a laser beam incident on the first side of the solar cell structure. The apparatus is configured for providing the adhesive on the second side of the solar cell structure.

According to a further embodiment, an apparatus for processing a solar cell structure is provided. The apparatus includes: a support system configured for supporting a solar cell structure; a laser unit configured for at least one of scribing the solar cell structure and cutting through the solar cell structure; an adhesive application unit configured for providing an adhesive on the solar cell structure; a flipping unit configured for turning over the solar cell structure; and an assembling unit configured for assembling a solar cell arrangement comprising a plurality of partially overlapping solar cell pieces.

According to a further embodiment, a method is provided. The method includes: providing a solar cell structure having a first side and a second side; directing a laser beam onto the first side of the solar cell structure to scribe the solar cell structure or to cut through the solar cell structure; separating the solar cell structure into two or more solar cell pieces, the two or more solar cell pieces comprising at least a first solar cell piece, the first solar cell piece having a first side and a second side; and providing a first adhesive on the second side of the first solar cell piece.

According to a further embodiment, an apparatus is provided. The apparatus includes: a support system comprising one or more support units for supporting a solar cell structure; a laser unit configured for at least one of scribing the solar cell structure and cutting through the solar cell structure; a separation device configured for separating the solar cell structure in two or more solar cell pieces, the two or more solar cell pieces comprising at least a first solar cell piece, the separation device comprising at least one of the laser unit and a cleaving unit configured for applying a force to the solar cell structure; and an adhesive application unit. The apparatus is configured for directing a laser beam onto a first side of the solar cell structure to scribe the solar cell structure or to cut through the solar cell structure. The apparatus is configured for providing a first adhesive on a second side of the first solar cell piece.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIGS. 1a-c illustrate a method for processing a solar cell structure according to embodiments described herein;

FIG. 2 shows an example of a solar cell structure according to embodiments described herein;

FIG. 3 illustrates scribing a solar cell structure according to embodiments described herein;

FIG. 4 shows an example of a solar cell structure in a sunny-up configuration according to embodiments described herein;

FIG. 5 illustrates providing an adhesive on a solar cell structure according to embodiments described herein;

FIG. 6 illustrates separating a solar cell structure into solar cell pieces according to embodiments described herein;

FIG. 7 illustrates an assembly of solar cell pieces according to embodiments described herein;

FIG. 8 illustrates curing a solar cell arrangement according to embodiments described herein;

FIG. 9 shows a shingled solar cell arrangement according to embodiments described herein;

FIG. 10a-c illustrate the aligning of a solar cell structure and a laser unit relative to each other according to embodiments described herein;

FIG. 11 shows an example of a solar cell structure according to embodiments described herein;

FIGS. 12a-c illustrate aligning a solar cell structure and an adhesive application unit relative to each other according to embodiments described herein;

FIGS. 13a-b show an apparatus for processing a solar cell structure according to embodiments described herein; and

FIG. 14 shows an apparatus for processing a solar cell structure according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Generally, only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

Some embodiments described herein involve the notion of a substantially vertical direction, plane, orientation and the like. A substantially vertical direction may deviate from exact verticality (the latter being defined by the gravitational force) by an angle of, e.g., up to 10 or even 15 degrees. Some embodiments described herein may involve the notion of a substantially horizontal direction, plane, orientation, and the like. A substantially horizontal direction may be substantially perpendicular to the exact vertical direction defined by gravity. The terminology of substantially perpendicular directions may include directions which form an angle of less than 90 degrees with each other, e.g. at least 80 degrees or at least 75 degrees.

A method for processing a solar cell structure, as described herein, can be a method for manufacturing a shingled solar cell arrangement. A shingled solar cell arrangement can be made of a plurality of partially overlapping solar cell pieces. Adjacent solar cell pieces are electrically connected to each other in the overlapping region. The solar cell pieces are connected in series such that current generated by the individual solar cell pieces flows along the series of solar cell pieces to be collected, for example, at an end portion of the solar cell arrangement. The overlapping configuration can provide high-efficiency solar cell arrangements. In particular, the solar cell arrangements allow increasing a solar cell module power by increasing a used or active area. Typically, the overlapping configuration can increase the module power by, for example, 20 to 40 Watts. The used or active area can correspond to an area that is irradiated by solar light and that participates in the generation of power. For example, the used or active area can correspond to an area of the solar cells that is not covered by, for example, conductive line patterns, such as fingers and/or bus bars.

The term “solar cell piece”, as used herein, is distinguished from the terms “solar cell” and “solar cell structure”. A solar cell piece, as described herein, refers to a portion or segment of a solar cell or solar cell structure. A solar cell piece may be understood as a solar cell segment, or solar cell shingle. A solar cell piece may be a segment of a solar cell structure resulting from separating the solar cell structure into solar cell pieces, e.g. by cleaving the solar cell structure or by laser singulation of the solar cell structure. The area of a solar cell piece is smaller than the area of a solar cell or solar cell structure. For example, the area of a solar cell piece may be 90% or less of the area of a solar cell structure. In some cases, a solar cell piece may have an area of 50% or less of the area of a solar cell structure.

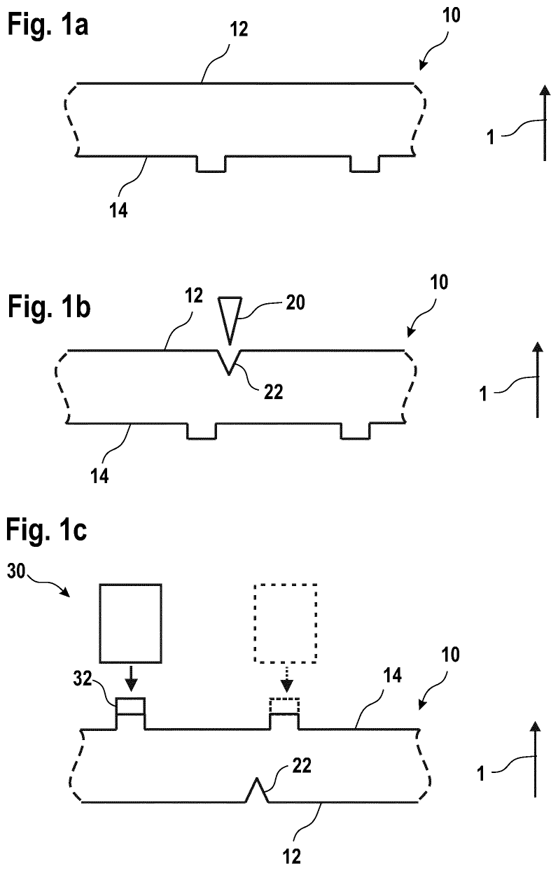

According to an embodiment, a method for processing a solar cell structure 10 is provided. Aspects of the method are illustrated in FIGS. 1a-c. The solar cell structure 10 in FIGS. 1a-c is provided in a substantially horizontal orientation. Direction 1 is a vertical direction. The arrow of direction 1 indicates an upward direction.

The method includes providing a solar cell structure 10, as illustrated in FIG. 1a. The solar cell structure has a first side 12 and a second side 14. The second side 14 opposes the first side 12.

A solar cell structure, as described herein, may be a substantially planar structure, e.g. a planar structure having a first length in a first direction, a second length in a second direction and a thickness which is much smaller than the first length and the second length. A solar cell structure may be a solar cell having a conductive pattern provided thereon, e.g. a plurality of fingers and/or bus bars. According to embodiments described herein, a solar cell structure has two sides, namely a first side 12 and a second side 14 opposite to the first side. The first side 12 and the second side 14 may be opposing sides or surfaces of a substantially planar solar cell structure. The first side 12 may be separated from the second side 14 by a thickness of the solar cell structure.

A solar cell structure, as described herein, may be a solar cell.

A solar cell structure or solar cell piece may have a sunny side, or front side. The terms “sunny side” and “front side” are used interchangeably herein. A solar cell structure or solar cell piece may have a back side. The front side is opposite to the back side. The first side of a solar cell structure or solar cell piece can be one of the front side and the back side. The second side of the solar cell structure or solar cell piece can be the other one of the front side and the back side.

The front side of a solar cell structure or solar cell piece is configured for receiving electromagnetic radiation, e.g. sunlight. The solar cell structure or solar cell piece is configured for converting the electromagnetic radiation into electrical power. The front side of a solar cell structure or solar cell piece may be the side of the solar cell structure or solar cell piece on which a conductive pattern comprising a plurality of fingers is provided. The back side of a solar cell structure or solar cell piece may not be configured to be exposed to sunlight.

A method, as described herein, may include scribing a solar cell structure on the first side of the solar cell structure. Alternatively or additionally, the method may include cutting through the solar cell structure using a laser beam incident on the first side of the solar cell structure.

FIGS. 1a-c illustrate the scribing of a portion 22 of a solar cell structure 10 on the first side 12 of the solar cell structure 10. Scribing the solar cell structure on the first side of the solar cell structure may include scribing the solar cell structure using a laser beam incident on the first side of the solar cell structure. For example, FIG. 1b shows a portion 22 which is scribed by a laser beam 20.

The scribing of a solar cell structure, as described herein, may refer to a process in which part of the material of the solar cell structure is removed from the solar cell structure, e.g. by a laser. For example, a thin, line-like portion of the solar cell structure may be removed for forming a groove in the solar cell structure. As another example, scribing the solar cell structure may include removing a plurality of point-like regions arranged along a substantially straight line across the solar cell structure.

A scribed portion of a solar cell structure, as described herein, may define a breaking location, e.g. a breaking line, for separating the solar cell structure into solar cell pieces. The scribed portion facilitates separating, e.g. breaking, the solar cell structure into solar cell pieces. For example, a groove scribed in the solar cell structure may define a breaking line of the solar cell structure. By applying a force to the scribed portion, e.g. a vertical force pushing against the solar cell structure, a solar cell structure can be separated into solar cell pieces or shingles. The process of applying a force to the solar cell structure for separating or breaking the solar cell structure into solar cell pieces may be referred to as cleaving the solar cell structure.

As illustrated for example in FIGS. 1a-c, a method as described herein may include providing an adhesive 32 on the second side 14 of the solar cell structure 10. For example, FIG. 1c shows an adhesive 32 being provided on the solar cell structure 10 by an adhesive application unit 30. Further adhesives may be applied on the second side 14 of the solar cell structure 10, as indicated by the dashed lines.

An adhesive, as described herein, is configured for connecting, particularly attaching, solar cell pieces to each other. The adhesive can be configured for connecting a first solar cell piece to a second solar cell piece. The first solar cell piece and the second solar cell piece can be obtained by separating a solar cell structure 10 into solar cell pieces. Alternatively, the first solar cell piece can be obtained by separating a first solar cell structure into solar cell pieces, and the second solar cell piece can be obtained by separating a second solar cell structure into solar cell pieces. That is, the solar cell pieces connected by an adhesive may be pieces of different solar cells. The adhesive can provide for an electrical and mechanical connection between two solar cell pieces. The adhesive can be in a substantially liquid form when the adhesive is applied to the solar cell structure.

An adhesive, as described herein, can be an electrically conductive adhesive (ECA). The adhesive can be selected from the group consisting of solder, silver paste, silicone-based electrically conductive adhesive, and epoxy-based electrically conductive adhesive.

In the exemplary embodiment shown in FIGS. 1a-c, the solar structure 10 shown in FIG. 1c is turned upside down as compared to the solar cell structure shown in FIG. 1b. In FIG. 1b, the first side 12 of the solar cell structure 10 faces upward. In FIG. 1c, the second side 14 of the solar cell structure 10 faces upward.

In light of the above, embodiments described herein provide a method for processing a solar cell structure, wherein the solar cell structure may be scribed on one side of the solar cell structure and the adhesive may be provided on the opposite side of the solar cell structure. Scribing the solar cell structure and providing the adhesive on different sides of the solar cell structure provides the advantage that there is less contamination. For example, dust or particles may be generated during the laser processing, e.g. laser scribing, of the solar cell structure. The adhesive may be provided, e.g. printed, on the solar cell structure in a liquid form, e.g. in the form of a conductive paste. By providing the adhesive on the opposite side of the solar structure as compared to the scribed portion, any dust generated in the scribing process cannot reach the adhesive. In light thereof, contamination of the adhesive can be reduced or even prevented. A reduced contamination provides for improvements with regard to resistivity and adhesion of the adhesive.

The second side 14 of a solar cell structure, as described herein, may be the front side or sunny side of the solar cell structure. Additionally or alternatively, the first side 12 of a solar cell structure may be the back side of the solar cell structure.

Embodiments described herein provide for a method wherein the adhesive may be provided, e.g. printed, on the front side of a solar cell structure, or on the front side of a solar cell piece. A process wherein the adhesive is provided on the front side of a solar cell structure or solar cell piece facilitates performing an alignment of the adhesive with respect to the structures or patterns on the front side of the solar cell structure or solar cell piece. The alignment can be provided prior to applying the adhesive on the solar cell structure or solar cell piece. Particularly, the adhesive may be aligned with respect to a conductive structure or pattern, e.g. one or more bus bars, on the front side of the solar cell structure or solar cell piece. Due to the alignment operation, the adhesive can be positioned in an accurate manner on top of a corresponding bus bar on the front side of the solar cell structure or solar cell piece. For example, it can be ensured that the adhesive is positioned entirely on the bus bar, which may improve adhesion and meet customer demands regarding the design of the solar cell structure. It can be avoided that parts of the adhesive touch regions of the solar cell structure next to the bus bar. In contrast, methods wherein the adhesive is applied to a back side of the solar cell structure or solar cell piece, particularly methods wherein the adhesive is applied to the adhesive in a sunny-down configuration of the solar cell structure, may not easily allow for an adhesive which is well-aligned with the front side of the solar cell structure.

During the providing the adhesive on a solar cell structure, the second side 14 of the solar cell structure may face upward. For example, in FIG. 1c, the second side 14 of the solar cell structure faces upward.

The second side 14 of a solar cell structure may be the front side or sunny side of the solar cell structure. During the providing the adhesive on the solar cell structure, the front side of the solar cell structure may face upward. A configuration wherein the front side, or sunny side, of a solar cell structure faces upward is referred to herein as a sunny-up configuration.

Embodiments described herein provide a method for processing a solar cell structure and/or solar cell piece, wherein several parts of the method are performed in a sunny-up configuration of the solar cell structure or solar cell piece. For example, the adhesive 32 may be provided on the solar cell structure 10 while the solar cell structure 10 is in a sunny-up configuration. As described below, other parts of the method can also be performed in a sunny-up configuration, e.g. the cleaving of solar cell structures and the assembling of solar cell pieces to form a shingled solar cell arrangement. As described above, processing a solar cell structure or solar cell piece in a sunny-up configuration facilitates performing an alignment of the adhesive with respect to the front side of the solar cell structure or solar cell piece. Further, processing a solar cell structure or solar cell piece in a sunny-up configuration facilitates performing a photoluminescence inspection of the solar cell structure or of pieces of the solar cell structure, e.g. before or after separating the solar cell structure into solar cell pieces. Still further, processing the solar cell structure or solar cell piece in a sunny-up configuration makes it easier to implement a last sunny-side bus bar of a shingled solar cell arrangement in a manner such that the last sunny-side bus bar is wider as compared to the other sunny-side bus bars of the shingled solar cell arrangement. Still further, processing the solar cell structure or solar cell piece in a sunny-up configuration facilitates chucking the solar cell structure, particularly for solar cell structures with a degree of bowing.

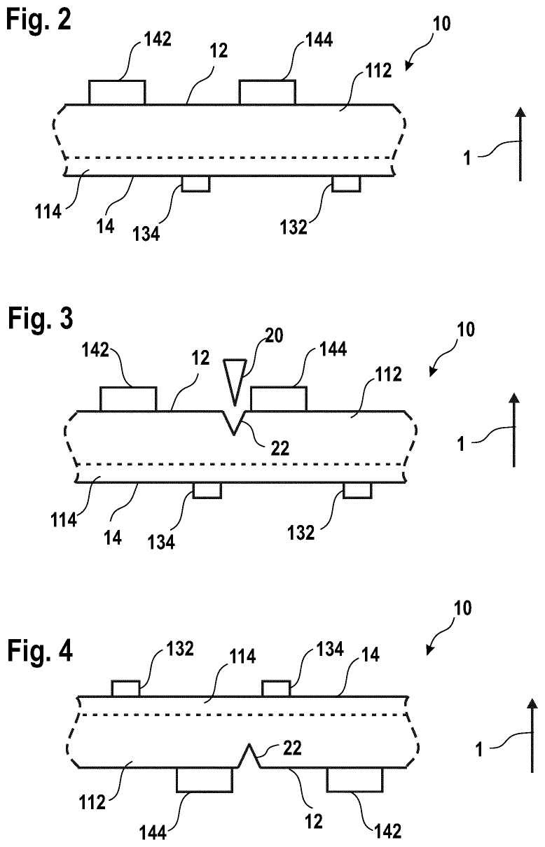

FIG. 2 shows a solar cell structure 10 according to embodiments described herein. The solar cell structure 10 includes a photovoltaic area 114. The photovoltaic area 114 is configured for receiving sunlight for converting the sunlight into electrical power. The photovoltaic area 114 defines the front side of the solar cell structure 10. In the exemplary embodiment shown in FIG. 2, the photovoltaic area 114 defines the second side 14 of the solar cell structure 10.

The exemplary solar cell structure 10 shown in FIG. 2 includes a bus bar 132 and a bus bar 134. The bus bars 132 and 134 are provided on the second side 14 of the solar cell structure 10. The bus bars 132 and 134 are examples of sunny-side bus bars as described herein. The solar cell structure 10 may include a conductive pattern or conductive structure including further bus bars and/or a plurality of fingers on the second side 14 of the solar cell structure 10.

The solar cell structure 10 shown in FIG. 2 includes a backside area 112. In the exemplary embodiment shown in FIG. 2, the backside area 112 defines the first side 12 of the solar cell structure 10.

The solar cell structure 10 shown in FIG. 2 includes a bus bar 142 and a bus bar 144. The bus bars 142 and 144 are provided on the first side 12 of the solar cell structure 10. The bus bars 142 and 144 are examples of backside bus bars as described herein.

In FIG. 2, the solar cell structure 10 is shown in a sunny-down configuration, wherein the sunny side of the solar cell structure faces downward. The back side of the solar cell structure 10 faces upward.

FIG. 3 illustrates scribing the solar cell structure 10 according to embodiments described herein. In FIG. 3, the solar cell structure 10 is shown in a sunny-down configuration, similar to the solar cell structure 10 shown in FIG. 2.

In the exemplary embodiment shown in FIG. 3, a portion 22 of the backside area 112 is scribed. The scribing is performed from above the solar cell structure 10. In the exemplary embodiment, the scribing is performed by a laser beam 20. A portion 22, e.g. a groove extending in a direction perpendicular to the drawing plane, is scribed in the backside area 112. The scribed portion 22 defines a breaking location for separating the solar cell structure 10 into separate solar cell pieces, e.g. as illustrated in FIG. 6. In the exemplary embodiment shown in FIG. 3, the scribed portion 22 is between the bus bar 142 and the bus bar 144.

During the scribing of a solar cell structure, the first side 12 of the solar cell structure may face upward. The first side 12 of the solar cell structure may be the back side of the solar cell structure. During the scribing, the front side of the solar cell structure may face downward. During the scribing, the solar cell structure may be in a substantially horizontal orientation. The scribing of a solar cell structure may be performed by a laser unit as described herein. During the scribing, the laser unit may be positioned above the solar cell structure. The scribing of a solar cell structure may be or include laser scribing.

A method, as described herein, may include scribing a plurality of portions of the solar cell structure on the first side 12 of the solar cell structure. Each scribed portion may define a respective breaking location for separating the solar cell structure into respective solar cell pieces.

FIG. 4 shows a solar cell structure 10 similar to the solar cell structure 10 shown in FIG. 3. The solar cell structure 10 shown in FIG. 4 is in a sunny-up configuration, wherein the front side, or sunny side, of the solar cell structure faces upward. The back side faces downward. As compared to the solar cell structure 10 in the sunny-down position shown in FIG. 3, the solar cell structure 10 shown in FIG. 4 has been turned over, i.e. flipped, to provide the solar cell structure 10 in a sunny-up position as shown in FIG. 4.

A method, as described herein, may include turning over, or flipping, the solar cell structure from a first position into a second position. The turning over of the solar cell structure may be performed after scribing the solar cell structure and/or before providing the adhesive on the solar cell structure. In the first position of the solar cell structure, the first side 12 of the solar cell structure may face upward. In the first position of the solar cell structure, the back side of the solar cell structure may face upward. Additionally or alternatively, in the second position of the solar cell structure, the second side 14 of the solar cell structure may face upward. In the second position of the solar cell structure, the front side of the solar cell structure may face upward.

Turning over the solar cell structure may be performed by a flipping unit as described herein. Turning over the solar cell structure may include: picking up the solar cell structure; rotating the solar cell structure to change the orientation of the solar cell structure from a first orientation wherein the first side of the solar cell structure faces upward to a second orientation wherein the second side of the solar cell structure faces upward; and putting down the rotated solar cell structure, e.g. on a support system.

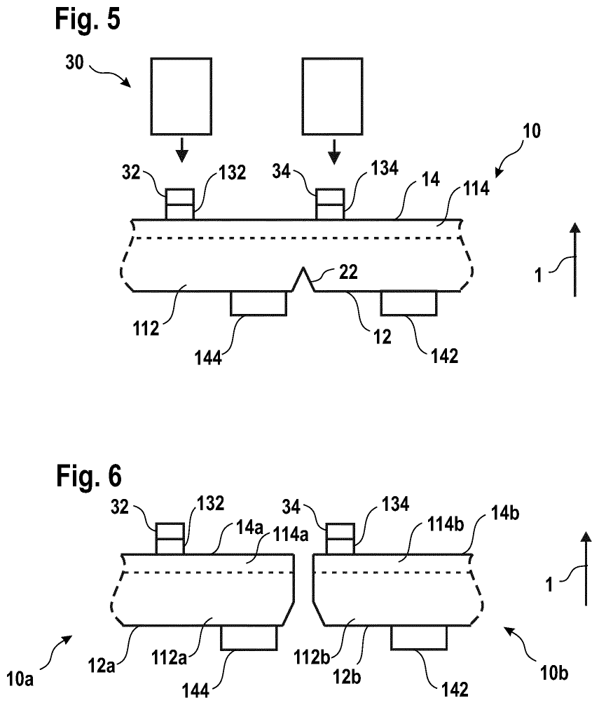

FIG. 5 shows a solar cell structure 10 being processed by an adhesive application unit 30. In FIG. 5, the solar cell structure 10 is in a sunny-up configuration, similar to the solar cell structure 10 shown in FIG. 4.

The adhesive application unit 30 shown in FIG. 5 is configured to provide at least adhesives 32 and 34 on the solar cell structure 10. An adhesive application unit 30 can be a printing unit configured for printing adhesives on a solar cell structure 10. The adhesives 32 and 34 are provided on the second side 14 of the solar cell structure 10. In the exemplary embodiment shown in FIG. 5, the second side 14 is the front side of the solar cell structure 10. In the exemplary embodiment shown in FIG. 5, the adhesive 32 is provided on the bus bar 132. The adhesive 34 is provided on the bus bar 134.

Providing an adhesive on the second side of a solar cell structure may include printing the adhesive on the second side of the solar cell structure. Providing the adhesive on the solar cell structure may be performed by an adhesive application unit. The adhesive application unit may be positioned above the solar cell structure.

A solar cell structure may include a conductive structure or a conductive pattern, particularly a conductive line pattern. A conductive pattern or structure can include one or more bus bars and/or a plurality of fingers. The solar cell structure can include a conductive pattern or structure on the front side of the solar cell structure. Additionally or alternatively, the solar cell structure can include a conductive pattern or structure on the back side of the solar cell structure. For example, the solar cell structure can include a first conductive pattern including one or more bus bars and a plurality of fingers on the front side of the solar cell structure. The solar cell structure can include a second conductive pattern including one or more bus bars on the back side of the solar cell structure.

Providing an adhesive on a solar cell structure can include providing the adhesive on at least a portion of a conductive structure or pattern of the solar cell structure, particularly a conductive pattern on the front side of the solar cell structure. Providing the adhesive on the solar cell structure may include providing the adhesive on a bus bar of the solar cell structure. The adhesive may be provided on a bus bar, wherein the bus bar is provided on a photovoltaic area of the solar cell structure.

An adhesive, as described herein, can be a first adhesive, e.g. adhesive 32 shown in the figures. The method can include providing, e.g. printing, a second adhesive on the second side 14 of a solar cell structure, e.g. adhesive 34 shown in the figures. The first adhesive and the second adhesive may be provided on the solar cell structure at a distance from each other. The first adhesive and the second adhesive may be provided on opposite sides of the scribed portion. The second adhesive can be provided on at least a portion of a conductive pattern of the solar cell structure. The first adhesive can be provided on a first bus bar of the solar cell structure and the second adhesive can be provided on a second bus bar of the solar cell structure.

During the providing of an adhesive on a solar cell structure or solar cell piece, the solar cell structure or solar cell piece may be in a substantially horizontal orientation.

Providing one or more adhesives on the second side 14 of a solar cell structure, as described herein, may be performed before the solar cell structure is separated into solar cell pieces.

FIG. 6 illustrates separation of a solar cell structure into solar cell pieces according to embodiments described herein.

FIG. 6 shows a first solar cell piece 10a and a second solar cell piece 10b. The first solar cell piece 10a and the second solar cell piece 10b can be provided by separating the solar cell structure 10 shown in FIG. 5 into pieces, particularly by cleaving the solar cell structure 10. The solar cell structure 10 can be separated into the solar cell pieces 10a and 10b by applying a force to the solar cell structure 10. The force can be applied to the backside area 112. The force can be applied at the scribed portion 22. The force can be substantially parallel to direction 1.

While applying a force to the solar cell structure 10 for separating the solar cell structure 10 into solar cell pieces 10a and 10b, the solar cell structure 10 can be in a sunny-up configuration.

In the exemplary embodiment shown in FIG. 6, the first solar cell piece 10a includes a first portion 114a of the photovoltaic area 114. The first solar cell piece 10a includes a first portion 112a of the backside area 112. The first solar cell piece 10a includes the adhesive 32. The first solar cell piece 10a includes the bus bar 132. The first solar cell piece 10a includes the bus bar 144. In the exemplary embodiment shown in FIG. 6, the second solar cell piece 10b includes a second portion 114b of the photovoltaic area 114. The second solar cell piece 10b includes a second portion 112b of the backside area 112. The second solar cell piece 10b includes the adhesive 34. The second solar cell piece 10b includes the bus bar 134. The second solar cell piece 10b includes the bus bar 142.

The first solar cell piece 10a shown in FIG. 6 has a first side 12a and a second side 14a opposite the first side 12a. The first side 12a and the second side 14a correspond to the first side 12 and the second side 14, respectively, of the solar cell structure 10 from which the first solar cell piece 10a was obtained. In the exemplary embodiment shown in FIG. 6, the second side 14a is the front side of the first solar cell piece 10a. The first solar cell piece 10a shown in FIG. 6 is in a sunny-up configuration.

The second solar cell piece 10b shown in FIG. 6 has a first side 12b and a second side 14b opposite the first side 12b. The first side 12b and the second side 14b correspond to the first side 12 and the second side 14, respectively, of the solar cell structure 10 from which the second solar cell piece 10b was obtained. In the exemplary embodiment shown in FIG. 6, the second side 14b is the front side of the second solar cell piece 10b. The second solar cell piece 10b shown in FIG. 6 is in a sunny-up configuration.

A method, as described herein, may include cleaving the solar cell structure. Cleaving the solar cell structure is performed for separating the solar cell structure into solar cell pieces, or shingles. Cleaving a solar cell structure may be performed at a scribed portion of the solar cell structure. The scribed portion provides a breaking location which facilitates separating the solar cell structure into solar cell pieces. The cleaving may include acting on the solar cell structure, particularly on a scribed portion of the solar cell structure, by a force, particularly a substantially vertical force. The force is configured for separating the solar cell structure into solar cell pieces or solar cell shingles. By applying the force, the solar cell structure breaks into separate solar cell pieces, wherein the breaking location(s) may be defined by the scribed portion(s) on the solar cell structure. The force can be an upward force, e.g. an upward force pushing up against a downward-facing scribed portion of the solar cell arrangement.

During the cleaving of a solar cell structure, the second side 14 of the solar cell structure may face upward. During the cleaving, the front side of the solar cell structure may face upward. The second side 14 of the solar cell structure can be the front side of the solar cell structure. During the cleaving, the solar cell structure may be provided in a substantially horizontal orientation.

The cleaving of a solar cell structure may be performed after scribing the solar cell structure. Additionally or alternatively, the cleaving of a solar cell structure may be performed after providing one or more adhesives on the solar cell structure.

A method, as described herein, may include separating a solar cell structure into a plurality of solar cell pieces by applying a force, particularly an upward force, to the solar cell structure. Each of the plurality of solar cell pieces may have a first side, a second side, a sunny side and/or a back side. The sides of the solar cell pieces correspond to the respective sides of the solar cell structure from which the solar cell pieces are obtained.

The plurality of solar cell pieces may include a first solar cell piece 10a, or first solar cell shingle. The first solar cell piece may include a front side and a back side. The plurality of solar cell pieces may include a second solar cell piece 10b, or second solar cell shingle. The second solar cell piece may include a front side and a back side.

The first solar cell piece may include the adhesive 32, particularly on the front side of the first solar cell piece. Additionally or alternatively, the first solar cell piece may include a bus bar on the front side of the first solar cell piece, particularly wherein the adhesive is provided on the bus bar. Additionally or alternatively, the first solar cell piece may include a further bus bar on the back side of the first solar cell piece.

The second solar cell piece may include an adhesive 34, particularly on the front side of the second solar cell piece. Additionally or alternatively, the second solar cell piece may include a bus bar on the front side of the second solar cell piece, particularly wherein the adhesive is provided on the bus bar. Additionally or alternatively, the second solar cell piece may include a further bus bar at a back side of the second solar cell piece.

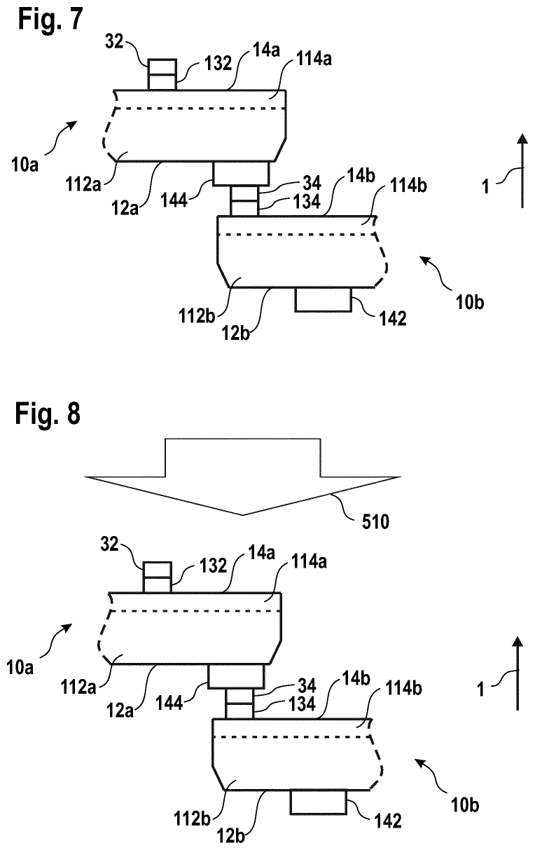

FIG. 7 illustrates an assembly of solar cell pieces according to embodiments described herein.

FIG. 7 shows the first solar cell piece 10a and the second solar cell piece 10b. The first solar cell piece 10a is attached to the second solar cell piece 10b. The adhesive 34 of the second solar cell piece 10b provides for a connection between the first solar cell piece 10a and the second solar cell piece 10b. In the exemplary embodiment shown in FIG. 7, the adhesive 34 connects the bus bar 144 on the back side of the first solar cell piece 10a to the bus bar 134 on the front side of the second solar cell piece 10b.

In the exemplary embodiment shown in FIG. 7, the first solar cell piece 10a is attached to the second solar cell piece 10b in a manner such that the first solar cell piece 10a is above the second solar cell piece 10b. A solar cell arrangement including a plurality of partially overlapping solar cell pieces is obtained. As shown, the solar cell arrangement can have a step-like configuration. A peripheral portion on the right hand side of the first solar cell piece 10a overlaps with a peripheral portion on the left hand side of the second solar cell piece 10b.

In the exemplary embodiment shown in FIG. 7, the connection between the first solar cell piece 10a and the second solar cell piece 10b is performed in a sunny-up configuration of the solar cell pieces.

FIG. 7 shows an example wherein solar cell pieces obtained from a same solar cell structure are connected to each other. Alternatively or additionally, solar cell pieces obtained from different solar cells may be connected to each other in a similar manner as shown in FIG. 7. For example, a first solar cell piece obtained from a first solar cell structure may be connected, by an adhesive, to a second solar cell piece of a second solar cell structure different from the first solar cell structure.

A method, as described herein, may include connecting a plurality of solar cell pieces to each other to form a solar cell arrangement of partially overlapping solar cell pieces, particularly a shingled solar cell arrangement. Each solar cell piece of the plurality of solar cell pieces may have a respective front side. During the connecting of the plurality of solar cell pieces to each other, the respective front sides of the solar cell pieces may face upward. The connecting of the plurality of solar cell pieces may be performed in a substantially horizontal orientation of the solar cell pieces.

The plurality of solar cell pieces may include a first solar cell piece and a second solar cell piece. The method may include connecting the first solar cell piece to the second solar cell piece by an adhesive as described herein, e.g. adhesive 34 shown in the figures. The adhesive may be provided in an overlapping region of the first solar cell piece and the second solar cell piece. The adhesive may be an adhesive of the second solar cell piece. The adhesive may connect a bus bar at the front side of the second solar cell piece, e.g. bus bar 134 shown in the figures, to a bus bar at the back side of the first solar cell piece, e.g. bus bar 144 shown in the figures.

FIG. 8 illustrates curing a solar cell arrangement according to embodiments described herein.

FIG. 8 shows a solar cell arrangement including a first solar cell piece 10a and a second solar cell piece 10b connected to each other, e.g. similar to FIG. 7. A curing operation is performed, as indicated by the arrow 510. The curing operation is performed for curing the adhesives in the system, e.g. adhesive 34 connecting the first solar cell piece 10a to the second solar cell piece 10b. By curing the adhesives, a strong bond between the solar cell pieces is provided.

In the exemplary embodiment shown in FIG. 8, the curing of the solar cell arrangement is performed in a sunny-up configuration of the solar cell pieces.

A method, as described herein, may include curing a solar cell arrangement of partially overlapping solar cell pieces. The curing of the solar cell arrangement may be or include a curing of one or more adhesives of the solar cell arrangement. The curing may include a drying process for drying the one or more adhesives. The curing may include heating at least a portion of the solar cell arrangement, e.g. one or more portions corresponding to one or more overlapping regions of adjacent solar cell pieces of the solar cell arrangement.

A solar cell arrangement comprising a plurality of partially overlapping solar cell pieces may have a first side, a second side, a sunny side and/or a back side. The sides of the solar cell arrangement correspond to the respective sides of the solar cell pieces included in the solar cell arrangement. During the curing of the solar cell arrangement, the second side of the solar cell arrangement may face upward. The second side of the solar cell arrangement may be the front side of the solar cell arrangement. The curing of the solar cell arrangement comprising overlapping solar cell pieces may be performed by a curing unit as described herein.

The configurations shown in FIGS. 2 through 8 may represent a sequence of consecutive phases in an exemplary method for manufacturing a shingled solar cell arrangement. For example, a scribing operation as illustrated in FIG. 3 may be followed by turning over the solar cell structure as illustrated in FIG. 4; said turning over of the solar cell structure may in turn be followed by providing an adhesive on the solar cell structure as illustrated in FIG. 5; and so on. The phases of the manufacturing process described with respect to FIGS. 2 through 8 may take place one directly after the other, or one or more further operations may be performed in between. The plurality of phases depicted in said figures may, but need not, all be present in the manufacturing method. In some implementations of a method for manufacturing a shingled solar cell arrangement, some of the phases depicted in FIGS. 2 through 8 may be omitted or replaced by other operations.

A method, as described herein, may include at least one of the following: separating a solar cell structure into a plurality of solar cell pieces, the plurality of solar cell pieces comprising a first solar cell piece; assembling a solar cell arrangement comprising a plurality of partially overlapping solar cell pieces, the solar cell arrangement comprising the first solar cell piece; and curing the solar cell arrangement. The separating, the connecting and/or the curing may be performed in a sunny-up configuration. During the separating, the front side of the solar cell structure may face upward. During the connecting, the respective front sides of the plurality of solar pieces may face upward. During the curing, the front side of the solar cell arrangement may face upward.

During at least one of the separating, the connecting and the curing, the respective front sides of the solar cell structure, the solar cell pieces and the solar cell arrangement may face upward.

A solar cell structure 10, as described herein, may be an entity which is larger than the structures shown in the figures. For example, FIG. 2 shows a solar cell structure 10 including two sunny-side bus bars 132 and 134 and two backside bus bars 142 and 144. The structure shown in FIG. 2 may be a portion of a solar cell structure 10. The solar structure 10 may extend towards the left and/or towards the right beyond the structure shown in the figure. The solar cell structure 10 may include further sunny-side bus bars to the left of the bus bar 134 and/or to the right of bus bar 132. The solar cell structure 10 may include further backside bus bars on the left of the bus bar 142 and/or to the right of bus bar 144.

With regard to e.g. FIG. 3, a scribing operation may involve scribing the solar cell structure 10 at a plurality of locations not shown in FIG. 3, e.g. locations in between adjacent backside bus bars of the solar cell structure. With regard to e.g. FIG. 5, a phase of the process in which adhesives are provided on the solar cell structure 10 may include providing a plurality of adhesives on portions of the solar cell structure not shown in FIG. 5. For example, a plurality of adhesives may be provided on the second side 14 of the solar cell to the left of adhesive 32 and/or to the right of adhesive 34. With regard to e.g. FIG. 6, separating the solar cell structure 10 into solar cell pieces may include separating the solar cell into one or more pieces in addition to the first solar cell piece 10a and the second solar cell piece 10b shown in FIG. 6. The additional solar cell pieces may be formed by breaking the solar cell structure 10 at respective scribed portions, e.g. grooves, formed in the solar cell structure additional to scribed portion 22. With regard to e.g. FIGS. 7 and 8, connecting the pieces of the solar cell structure to each other may include connecting a plurality of solar cell pieces to each other. For example, the adhesive 32 of the first solar cell piece 10a as shown in FIG. 7 may be used for connecting the first solar cell piece 10a to a further solar cell piece arranged above the first solar cell piece 10a. The further solar cell piece can be connected to a yet further solar cell piece, and so on. Likewise, the second solar cell piece 10b may be connected to one or more additional solar cell pieces by way of respective adhesives. In light thereof, a shingled solar cell arrangement including a string of partially overlapping solar cell pieces can be obtained.

The exemplary process illustrated in FIGS. 2-8 may be modified in several respects, as described below. These modifications may be combined with each other.

When a laser beam is incident on the first side 12 of a solar cell structure 10, the first side, particularly the back side, of the solar cell structure may face upward, as e.g. illustrated in FIG. 3. The laser beam incident on the first side of the solar cell structure may be incident on the solar cell structure from above the solar cell structure. Alternatively, when a laser beam is incident on the first side of the solar cell structure, the first side, particularly the back side, of the solar cell structure may face downward. The laser beam incident on the first side of the solar cell structure may be incident on the solar cell structure from below the solar cell structure.

Providing an adhesive on the second side 14 of a solar cell structure 10, as described herein, may be performed after scribing the solar cell structure on the first side 12 of the solar cell structure, as e.g. illustrated in FIGS. 3-5. In some implementations, after the scribing and/or before the providing of the adhesive, the solar cell structure may be turned over, i.e. flipped, as e.g. illustrated in FIG. 4. Alternatively, the scribing of the solar cell structure and the providing of the adhesive can be performed without flipping the solar cell structure in between. For example, the scribing can be performed from below the solar cell structure and the adhesive can be printed from above the solar cell structure. During both the scribing and the providing of the adhesive, a same side, e.g. the front side, of the solar structure may face upward.

In yet another implementation, the providing of an adhesive on the second side 14 of the solar cell structure 10, as described herein, may be performed before the scribing of the solar cell structure 10. In some implementations, after the providing of the adhesive and/or before the scribing, the solar cell structure may be turned over. In other implementations, the providing of the adhesive and the scribing the solar cell structure can be performed without flipping the solar cell structure in between. For example, the adhesive can be printed from above the solar cell structure and the scribing can be performed from below the solar cell structure.

A laser beam incident on the solar cell structure 10 may be configured for scribing the solar cell structure. A scribing operation and a separate cleaving operation can be performed, as e.g. illustrated in FIGS. 3-6. Alternatively, the cleaving operation may be omitted. A laser beam incident on the solar cell structure may be configured for separating the solar cell structure in two or more solar cell pieces. The laser beam may be configured for cutting through the solar cell structure. For example, the laser beam may be configured for cutting through the solar cell structure during a scanning of the laser beam across the width of the solar cell structure. The process of separating a solar cell structure into solar cell pieces by cutting through the solar cell structure using a laser beam may be referred to as laser singulation. A laser beam incident on the first side of the solar cell structure may be configured for laser singulation of the solar cell structure.

In light of the above, embodiments described herein may involve laser singulation of a solar cell structure using a laser beam incident on one side of the solar cell structure (i.e. the first side) and providing an adhesive on the opposite side of the solar cell structure (i.e. the second side). As described above, contamination of the adhesive can be reduced or even prevented.

Cutting through the solar cell structure using a laser beam incident on the first side of the solar cell structure may be performed after providing an adhesive on the second side of the solar cell structure. In some implementations, after the providing of the adhesive and/or before the cutting through the solar cell structure, the solar cell structure may be turned over, i.e. flipped. In other implementations, the providing of the adhesive and the cutting through the solar cell structure can be performed without flipping the solar cell structure in between. For example, the adhesive can be printed from above the solar cell structure and the cutting through the solar cell structure can be performed from below the solar cell structure.

For example, a method as described herein may include a first operation and a second operation performed after the first operation. In the first operation, an adhesive may be printed on the front side of the solar cell structure while the solar cell structure is in a sunny-up configuration. In the second operation, the solar cell structure may be scribed or singulated on the back side of the solar cell structure, e.g. from below, while the solar cell structure is in a sunny-up configuration. The solar cell structure may not be flipped between the first operation and the second operation.

In another example, a method as described herein may include a first operation, a second operation performed after the first operation and a third operation performed after the second operation. In the first operation, an adhesive may be printed on the front side of the solar cell structure while the solar cell structure is in a sunny-up configuration. In the second operation, the solar cell structure may be flipped from a sunny-up configuration to a sunny-down configuration. In the third operation, the solar cell structure may be scribed or singulated on the back side of the solar cell structure while the solar cell structure is in a sunny-down configuration. In an optional fourth operation after the third operation, the solar cell structure may be flipped again. After the fourth operation, the solar cell structure or solar cell pieces may be cleaved and/or cured in a sunny-up configuration as described herein.

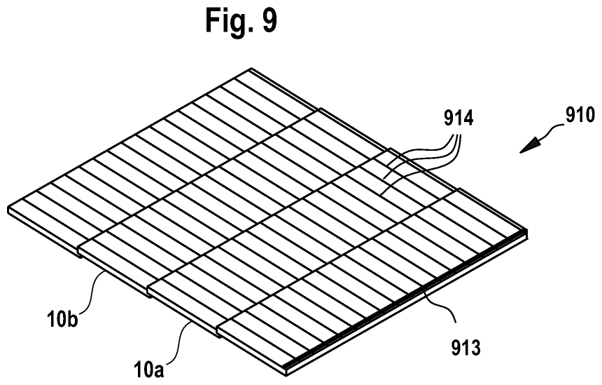

FIG. 9 shows a shingled solar cell arrangement 910 according to embodiments described herein. The shingled solar cell arrangement 910 can be manufactured according to embodiments of the methods described herein. The shingled solar cell arrangement 910 shown in FIG. 9 includes a string of partially overlapping solar cell pieces. The shingled solar cell arrangement 910 includes the first solar cell piece 10a, the second solar cell piece 10b, and further solar cell pieces. A solar cell piece can include a conductive pattern, e.g. a plurality of fingers 914 and/or one or more bus bars 913, on the first side and/or the second side of the solar cell piece.

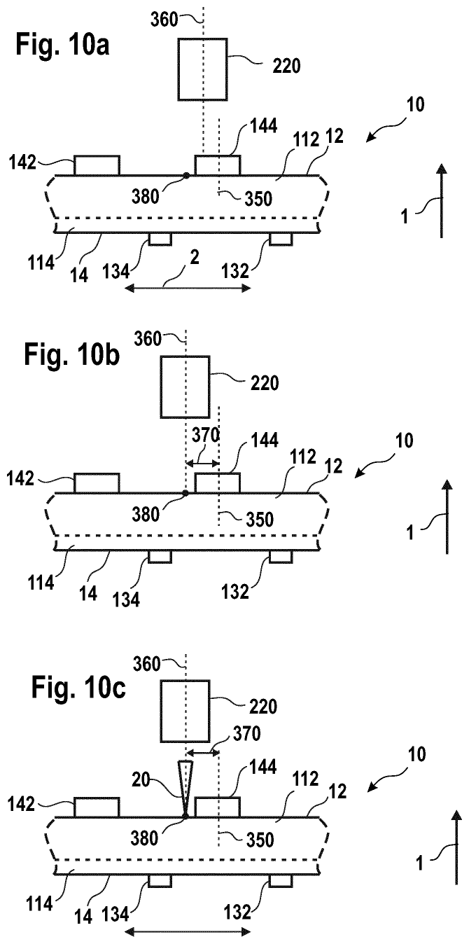

FIGS. 10a-c illustrate the aligning of a solar cell structure 10 and a laser unit 220 relative to each other, according to embodiments described herein. The laser unit 220 may be configured for at least one of scribing the solar cell structure 10 and cutting through the solar cell structure 10. FIG. 10a shows a laser unit 220 and a solar cell structure 10 in a configuration before an alignment operation has been performed. FIG. 10b shows the laser unit 220 and the solar cell structure 10 after the alignment operation has been performed. FIG. 10c shows the laser unit 220 and the solar cell structure 10 during the scribing of the solar cell structure 10 in the aligned configuration of FIG. 10b. The laser unit 220 may also be used for cutting though the solar cell structure 10 in the aligned configuration of FIG. 10b.

The exemplary laser unit 220 shown in FIG. 10a is arranged for scribing the solar cell structure 10 on the first side 12 of the solar cell structure 10. The laser unit 220 may, e.g., include a laser for laser scribing the solar cell structure 10. Axis 360 of the laser unit 220 corresponds to a path travelled by a laser beam which can be emitted by the laser unit 220 for scribing the solar cell structure 10. The axis 360 defines a position on the solar cell structure 10 at which a laser beam emitted by the laser unit 220 would impinge on the solar cell structure 10.

Before performing a scribing or cutting operation, the laser unit 220 and the solar cell structure 10 may be aligned relative to each other. For example, in the embodiment illustrated in FIGS. 10a-c, it is considered to scribe the solar cell structure 10 in a target location between the bus bar 144 and the bus bar 142. The target location is schematically indicated at 380. Before the scribing operation is performed, the laser unit 220 and the solar cell structure 10 can be in a configuration shown in FIG. 10a. In such a configuration, a laser beam that would be emitted by the laser unit 220 would impinge on the bus bar 144, as indicated by the axis 360. The laser beam would not impinge on the target location between the bus bar 144 and the bus bar 142. In light thereof, an alignment of the laser unit 220 and the solar cell structure 10 relative to each other can be performed.

The alignment of the laser unit 220 and the solar cell structure 10 relative to each other may be performed based on a position of a conductive structure or a conductive pattern of the solar cell structure 10. For example, in the embodiment illustrated in FIGS. 10a-c, the alignment may be performed based on a position of the bus bar 144 on the back side of the solar cell structure 10.

For example, a position of the bus bar 144 may be determined, e.g. by making an image of the first side 12 of the solar cell structure 10. Based on the determined position of the bus bar 144, a target position of the laser unit 220 relative to the bus bar 144 may be calculated, e.g. by a controller. For example, a target value for the distance from the axis 360 to axis 350 may be calculated.

Based on the calculated target position, the relative position of the laser unit 220 with respect to the solar cell structure 10 may be adjusted, e.g. along a horizontal direction 2. By adjusting said relative position, the laser unit 220 and the solar cell structure 10 can be provided in a well aligned configuration.

For example, FIG. 10b shows the solar cell structure 10 and the laser unit 220 after the alignment operation. In the configuration shown in FIG. 10b, the laser unit 220 is in a target position relative to the solar cell structure 10 for scribing the solar cell structure 10. The distance 370 from the axis 360 to the axis 350 corresponds to a target distance.

FIG. 10c shows the solar cell structure 10 and the laser unit 220 in the same relative position as shown in FIG. 10b, i.e. after the alignment operation has been performed. A laser beam 20 emitted by the laser unit impinges on the solar cell structure 10, particularly on the back side of the solar cell structure 10, at the target location between the bus bar 142 and the bus bar 144.

A method, as described herein, may include aligning a solar cell structure and a laser unit relative to each other. The aligning may be performed prior to at least one of scribing the solar cell structure and cutting through the solar cell structure. The aligning may be based on a position of at least a portion of a conductive structure or pattern of the solar cell structure, particularly a conductive structure or pattern on the first side of the solar cell structure. The aligning may be based on a relative position of the laser unit with respect to the conductive structure or pattern. The aligning may be based on the position of one or more bus bars of the solar cell structure, particularly one or more bus bars on the first side 12 of the solar cell structure. The aligning may be based on a relative position of the laser unit with respect to the one or more bus bars.

Performing the alignment based on a position of a conductive structure, e.g. a bus bar, of the solar cell structure has the advantage that a constant distance between the scribed portion and adjacent bus bars can be provided. In light thereof, a more uniform shape, e.g. a more uniform width, of the solar cell shingles can be provided. A more uniform shape of the solar cell pieces facilitates aligning the different solar cell pieces with respect to each other for forming the shingled solar cell arrangement. In contrast, an alignment which is based on the position of an edge of the solar cell structure, and not on a position of a conductive structure or pattern of the solar cell structure, may not guarantee that the distance between a scribed portion and the adjacent bus bar is constant.

Aligning the solar cell structure and the laser unit relative to each other may include displacing the solar cell structure and/or displacing at least a portion of the laser unit. The displacement may be provided in a substantially horizontal direction.

Aligning the solar cell structure and the laser unit relative to each other may include at least one of the following: providing an image of at least part of the first side 12 of the solar cell structure, e.g. by an inspection system such as a camera; determining a position of at least a portion of a conductive structure or pattern on the first side of the solar cell structure, wherein the position may be determined based on the image; and, based on the determined position, displacing the solar cell structure and/or displacing at least a portion of the laser unit to provide a target relative position of the solar cell structure and the laser unit.

During the aligning of a solar cell structure and the laser unit relative to each other, the first side 12, e.g. the back side, of the solar cell structure may face upward. During the aligning of the solar cell structure and the laser unit relative to each other, the front side of the solar cell structure may face downward.

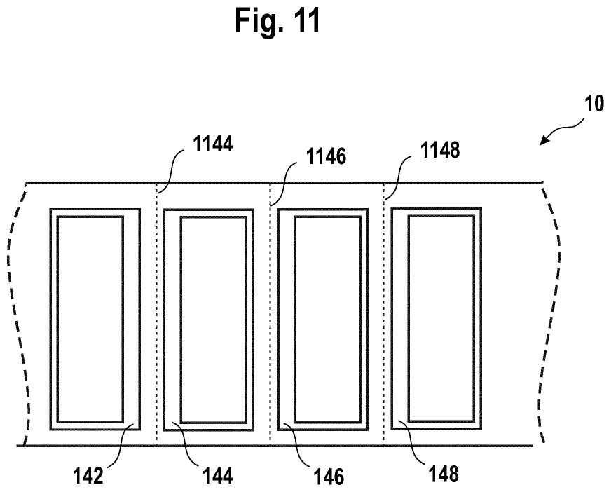

FIG. 11 shows a solar cell structure 10 including a conductive pattern including the bus bar 142, the bus bar 144 and further bus bars 146 and 148. The solar cell structure 10 includes a scribed portion 1144 between bus bar 142 and bus bar 144. The solar cell structure 10 includes a scribed portion 1146 between bus bar 144 and bus bar 146. The solar cell structure 10 includes a scribed portion 1148 between bus bar 146 and bus bar 148. The scribed portions 1144, 1146 and 1148 can be provided by a laser unit which is aligned relative to the solar cell structure 10 based on the position of the conductive pattern according to embodiments as described herein. The alignment operation can be based on the positions of the bus bars 142, 144, 146 and 148. By performing an alignment operation based on the position of the conductive pattern, a substantially constant distance can be provided between the scribed portions 1144, 1146 and 1148 and the respective bus bars 144, 146 and 148, as shown in FIG. 11.

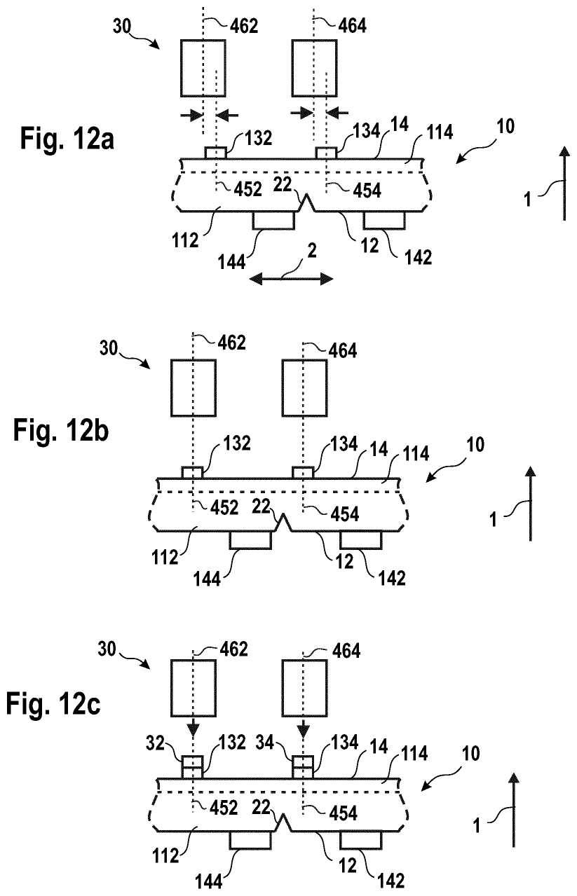

FIGS. 12a-c illustrate the aligning of a solar cell structure 10 and an adhesive application unit 30 relative to each other, according to embodiments described herein. FIG. 12a shows an adhesive application unit 30 and a solar cell structure 10 in a configuration before an alignment operation has been performed. FIG. 12b shows the adhesive application unit 30 and the solar cell structure 10 after the alignment operation has been performed. FIG. 12c shows the adhesive application unit 30 and the solar cell structure 10 during the application of adhesives on the solar cell structure 10 in the aligned configuration of FIG. 12b.

The adhesive application unit 30 shown in FIG. 12a is arranged for applying a plurality of adhesives on the second side 14 of the solar cell structure 10. In the exemplary embodiment shown, the second side 14 is the front side of the solar cell structure 10.

Before the adhesives are applied to the solar cell structure 10, the adhesive application unit 30 and the solar cell structure 10 can be in a configuration as shown in FIG. 12a. In such a configuration, an adhesive that would be provided by the adhesive application unit 30 would not be applied in a target position on the bus bar 132, as schematically indicated by an offset between axis 462 and axis 452. Similarly, a further adhesive that would be provided by the adhesive application unit 30 would not be applied on a target position on the bus bar 134, as schematically indicated by an offset between axis 464 and axis 454. In light thereof, a method as described herein may include aligning the solar cell structure and the adhesive application unit relative to each other. The aligning may be performed prior to applying an adhesive on the solar cell structure by the adhesive application unit.

Aligning the solar cell structure and the adhesive application unit relative to each other may include displacing the solar cell structure and/or displacing at least a portion of the adhesive application unit. The displacement may be provided in a substantially horizontal direction.

The aligning may be based on a position of at least a portion of a conductive structure, e.g. a conductive pattern, of the solar cell structure, particularly a conductive structure on the second side 14 of the solar cell structure. The aligning may be based on a relative position of the adhesive application unit with respect to the conductive structure. The aligning may be based on the position of one or more bus bars of the solar cell structure, particularly one or more bus bars on the second side 14 of the solar cell structure. The aligning may be based on a relative position of the adhesive application unit with respect to the one or more bus bars. For example, in the embodiment illustrated in FIGS. 12a-c, the alignment may be performed based on a position of the bus bar 132 and/or a position of the bus bar 134 located on the front side of the solar cell structure 10.

Aligning the solar cell structure and the adhesive application unit relative to each other may include at least one of the following: providing an image of at least part of the second side 14 of the solar cell structure, e.g. by a camera; determining a position of at least a portion of a conductive structure, e.g. a conductive pattern, on the second side of the solar cell structure, wherein the position may be determined based on the image; and, based on the determined position, displacing the solar cell structure and/or displacing at least a portion of the adhesive application unit to provide a target relative position of the solar cell structure and the adhesive application unit.

For example, a position of the bus bar 132 and/or of the bus bar 134 may be determined, e.g. by making an image of the second side 14 of the solar cell structure 10. Based on the determined position of the bus bar(s), a target position of the adhesive application unit 30 relative to the bus bar(s) may be calculated, e.g. by a controller. For example, a target position may be calculated such that, in the target position, the axis 462 aligns with the axis 452 and the axis 464 aligns with the axis 454.

Based on the calculated target position, the relative position of the adhesive application unit 30 with respect to the solar cell structure 10 may be adjusted. By adjusting said relative position, a configuration can be provided such that the position of the adhesive application unit 30 with respect to the solar cell structure 10 corresponds to the calculated target position. In light thereof, the adhesive application unit 30 and the solar cell structure 10 can be provided in a well aligned configuration.

For example, FIG. 12b shows the solar cell structure 10 and the adhesive application unit 30 after the alignment operation. In the configuration shown in FIG. 12b, the adhesive application unit 30 is in a target position relative to the solar cell structure 10 for applying the adhesives on the solar cell structure 10. The axis 462 is in alignment with the axis 452. The axis 464 is in alignment with the axis 454.

FIG. 12c shows the solar cell structure 10 and the adhesive application unit 30 in the same relative position as shown in FIG. 12b, i.e. after the alignment operation has been performed. An adhesive 32 provided by the adhesive application unit 30 is applied on the solar cell structure 10 at a target location, namely on the bus bar 132. An adhesive 34 provided by the adhesive application unit 30 is applied on the solar cell structure 10 at a target location, namely on the bus bar 134.

During the aligning of the solar cell structure and the adhesive application unit relative to each other, the second side of the solar cell structure may face upward. During the aligning of a solar cell structure and a laser unit relative to each other, the sunny side of the solar cell structure may face upward.

As described above, due to the alignment based on the position of a conductive pattern on the front side of the solar cell structure, the adhesive can be positioned in an accurate manner on top of a corresponding bus bar on the sunny side of the solar cell structure. Adhesion can be improved and customer demands regarding the design of the solar cell structure can be met. Further, an alignment based on the position of a conductive pattern on the front side of the solar cell structure may give better results as compared to an alignment based on the position of a conductive pattern on the back side of the solar cell structure, due to a better contrast. Further, an alignment based on the position of a conductive pattern on the front side of the solar cell structure may facilitate detecting whether a solar cell structure is arranged in the system in a wrong orientation. For example, the spatial arrangement of the conductive pattern on the front side of a solar cell structure may not be symmetrical. A solar cell structure may be rotated 180 degrees with respect to a target orientation, e.g. by mistake by an operator. Such an incorrect orientation of a solar cell structure can easily be detected and corrected in the alignment process, since the alignment process includes making an image of the front side of the solar cell structure. No additional hardware may be needed for detecting the incorrectly oriented solar cells.

According to a further embodiment, an apparatus for processing a solar cell structure is provided. The solar cell structure has a first side and a second side opposite the first side. The apparatus includes a support system including one or more support units for supporting a solar cell structure. The apparatus includes a laser unit configured for at least one of scribing the solar cell structure supported by the support system and cutting through the solar cell structure supported by the support system. The apparatus includes an adhesive application unit configured for providing an adhesive on the solar cell structure supported by the support system. The apparatus is configured for at least one of (a) scribing the solar cell structure on the first side of the solar cell structure and (b) cutting through the solar cell structure using a laser beam incident on the first side of the solar cell structure. The apparatus is configured for providing the adhesive on the second side of the solar cell structure.

According to a further embodiment, an apparatus for processing a solar cell structure is provided. The apparatus includes a support system configured for supporting a solar cell structure. The apparatus includes a laser unit configured for at least one of scribing the solar cell structure and cutting through the solar cell structure. The apparatus includes an adhesive application unit configured for providing an adhesive on the solar cell structure. The apparatus includes a flipping unit configured for turning over the solar cell structure. The apparatus includes an assembling unit configured for assembling a solar cell arrangement comprising a plurality of partially overlapping solar cell pieces.

An apparatus, as described herein, may be configured for performing any of the features of the methods described herein.

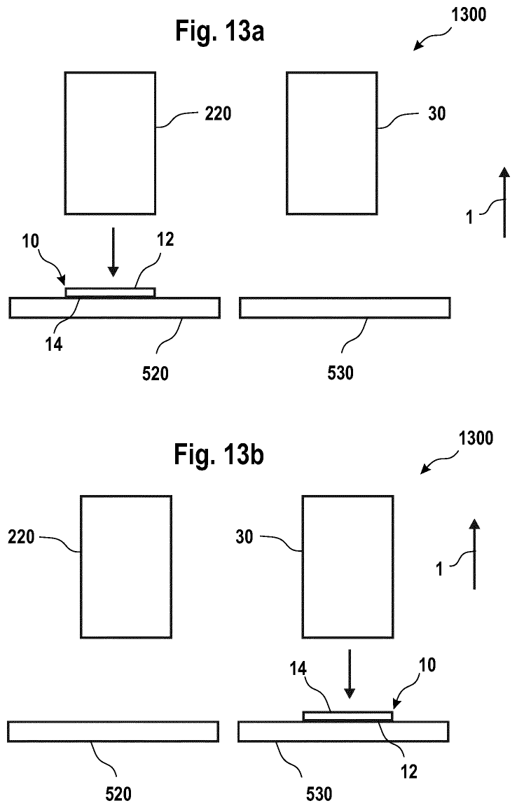

FIGS. 13a-b show an exemplary apparatus 1300 for processing a solar cell structure 10 according to embodiments described herein. The apparatus 1300 shown in FIGS. 13a-b includes a laser unit 220 and an adhesive application unit 30.

In the exemplary embodiment shown in FIGS. 13a-b, the apparatus 1300 includes a support unit 520 for supporting a solar cell structure while the solar cell structure is processed by the laser unit 220. As shown, the support unit 520 may be below the laser unit 220. In the exemplary embodiment shown in FIGS. 13a-b, the apparatus 1300 includes a support unit 530 for supporting a solar cell structure while the solar cell structure is processed by the adhesive application unit 30. The support unit 530 may be below the adhesive application unit 30.

A support system may be adapted for guiding a solar cell structure or solar cell piece, or a plurality of solar cell structures or pieces, in a transport direction of the apparatus. A support system can include one or more support units, e.g. support unit 520 and support unit 530. The one or more support units may be separate support units. Each support unit may serve a different part, unit or station of the apparatus. For example, the support system may include a first support unit serving the laser unit. The apparatus may include a second support unit separated from the first support unit for serving the adhesive application unit. Alternatively, the apparatus may include a common support system, e.g. a continuous transport system, serving different parts, units or stations of the apparatus. A support system may be configured for supporting a solar cell structure in a substantially horizontal orientation. A support system may include one or more belt conveyors.

FIG. 13a shows the apparatus 1300 in a first state of operation. A solar cell structure 10 is supported by the support unit 520. In the exemplary embodiment illustrated in FIG. 13a, the first side 12 of the solar cell structure 10 faces upward. The laser unit 220 performs a scribing operation on a portion of the solar cell structure 10 on the first side 12 of the solar cell structure 10. Alternatively or additionally, a laser unit 220 may also be configured for cutting through a solar cell structure, as described herein.

A scribing or cutting operation performed by a laser unit 220 may be preceded by an alignment of the laser unit 220 relative to the solar cell structure 10 as described herein. The apparatus 1300 may include an inspection system, e.g. including a camera, for making one or more images of a conductive pattern of the solar cell structure supported by the support unit 520. As described herein, based on the one or more images, the alignment may be provided.

After the scribing operation shown in FIG. 13a, the solar cell structure 10 may be transferred from the support unit 520 to the support unit 530.

An apparatus, as described herein, may be configured for providing a solar cell structure on the support system for scribing the solar cell structure by the laser unit in a manner such that, during the scribing, the first side of the solar cell structure faces upwards. The first side may be the back side of the solar cell structure.

A laser unit may include or be a laser. A laser unit, or at least a portion thereof, may be arranged above one or more support units of the support system. Alternatively, a laser unit, or at least a portion thereof, may be arranged below one or more support units of the support system. A laser unit can be configured for scribing a plurality of spaced apart regions of a solar cell structure. The laser unit may be configured for scribing the plurality of spaced apart regions in parallel.

An apparatus, as described herein, may include a first alignment unit for aligning a solar cell structure and a laser unit relative to each other. The aligning may be performed in the manner described herein.

The first aligning unit may include an inspection device, e.g. a camera, for making an image of at least part of the solar cell structure supported by the support system. The first aligning unit may include a controller configured for determining a position of at least a portion of a conductive pattern of the solar cell structure, particularly a conductive pattern on the first side of the solar cell structure. The position may be determined based on the image made by the inspection device. The first alignment unit may be configured for displacing the solar cell structure and/or displacing at least a portion of the laser unit based on the determined position to provide a target relative position of the solar cell structure and the laser unit.

FIG. 13b shows the apparatus 1300 in a second state of operation. The solar cell structure 10 is supported by the support unit 530. The second side, e.g. the sunny or front side, of the solar cell structure 10 faces upward. The adhesive application unit 30 provides one or more adhesives on the second side 14 of the solar cell structure 10. The application of the adhesives may be preceded by an alignment of the adhesive application unit 30 relative to the solar cell structure 10 as described herein. The apparatus 1300 may include an inspection system for making one or more images of a conductive pattern of the solar cell structure supported by the support 530. As described herein, based on the one or more images, the alignment may be provided.

An apparatus, as described herein, may be configured for providing a solar cell structure on the support system in a manner such that, during the providing the adhesive, the second side 14 of the solar cell structure faces upwards. The second side may be the front side of the solar cell structure.

An adhesive application unit, as described herein, may be an adhesive printing unit. The adhesive application unit may be configured for printing an adhesive on a solar cell structure or solar cell piece. An adhesive application unit can be configured for applying a plurality of adhesives on a solar cell structure at spaced apart locations. The adhesive application unit may be configured for providing the plurality of adhesives in parallel. An adhesive application unit may be arranged downstream of a laser unit relative to a processing flow of the apparatus. Alternatively, the adhesive application unit may be arranged upstream of the laser unit. The adhesive application unit may be arranged downstream of a flipping unit. An adhesive application unit may be arranged upstream of a cleaving unit.

An adhesive application unit, or at least a portion thereof, may be arranged above the support system. An adhesive application unit may be configured for providing, e.g. printing, an adhesive on top of a solar cell structure or solar cell piece supported by the support system.

The apparatus may include a second alignment unit for aligning a solar cell structure and the adhesive application unit relative to each other. The aligning may be performed in the manner described herein.

The second aligning unit may include an inspection device, e.g. including a camera, for making an image of at least part of the solar cell structure or solar cell piece supported by the support system. The second aligning unit may include a controller configured for determining a position of at least a portion of a conductive pattern of the solar cell structure or solar cell piece, particularly a conductive pattern on the second side of the solar cell structure or solar cell piece. The position may be determined based on the image made by the inspection device. The second alignment unit may be configured for displacing the solar cell structure or solar cell piece and/or for displacing at least a portion of the adhesive application unit based on the determined position to provide a target relative position of the solar cell structure/piece and the adhesive application unit.

The apparatus may be configured such that, during the aligning of the solar cell structure or piece and the adhesive application unit relative to each other, the second side of the solar cell structure or piece faces upward.

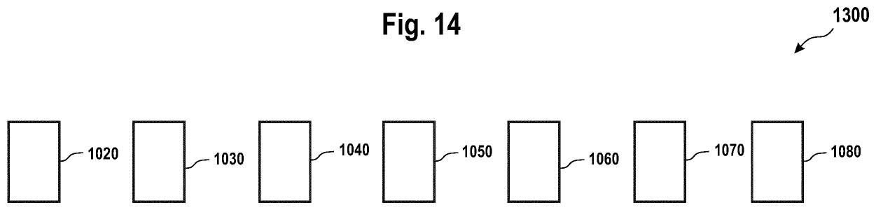

FIG. 14 shows an apparatus 1300 for processing a solar cell structure according to embodiments described herein. The apparatus 1300 is adapted for manufacturing a shingled solar cell arrangement.

In the exemplary embodiment shown in FIG. 14, the apparatus 1300 includes processing stations 1020, 1030, 1040, 1050, 1060, 1070 and 1080. An apparatus 1300 according to embodiments described herein need not include all of the processing stations depicted in FIG. 14. The apparatus 1300 may include only some of the processing stations.

For example, the processing station 1040, which may be a flipping station, and/or the processing station 1060, which may be a cleaving station, may be omitted.

The apparatus 1300 may include a processing line. The processing stations 1020, 1030, 1040, 1050, 1060, 1070 and 1080 may be provided along the processing line or processing flow. In FIG. 14, a solar cell structure may be processed from left to right. In the processing line, the processing station 1030 may be provided downstream of the processing station 1020; the processing station 1040 may be provided downstream of the processing station 1030; the processing station 1050 may be provided downstream of the processing station 1040; and so on.

Alternatively, the order of the processing stations shown in FIG. 14 may be changed according to embodiments described herein. For example, the processing station 1030, which may be a scribing station, may be arranged downstream of the processing station 1050, which may be an adhesive application station.

Processing station 1020 shown in FIG. 14 may be a storing station. A plurality of solar cell structures, e.g. solar cell structures 10 as shown in FIG. 2, may be stored and/or stacked in processing station 1020.

Processing station 1030 shown in FIG. 14 may be a scribing and/or cutting station. Processing station 1030 may include a laser unit as described herein. Processing station 1030 may include a first alignment unit for aligning the laser unit and the solar cell structure relative to each other, as described herein. Processing station 1030 may be a singulation station configured for performing a singulation of a solar cell structure as described herein.

Processing station 1040 shown in FIG. 14 may be a flipping station. Processing station 1040 may include a flipping unit.

A flipping unit, as described herein, may be configured for turning over a solar cell structure. Turning over solar cell structure may include: picking up the solar cell structure from the support system; rotating the solar cell structure to change the orientation of the solar cell structure from a first orientation wherein the first side of the solar cell structure faces upward to a second orientation wherein the second side of the solar cell structure faces upward; and putting down the rotated solar cell structure on the support system. Likewise, a flipping unit may be configured for turning over a solar cell piece. A flipping unit, or at least a portion thereof, may be arranged above the support system.

Processing station 1050 shown in FIG. 14 may be an adhesive application station. Processing station 1050 may include an adhesive application unit as described herein. An adhesive application unit may be configured for providing an adhesive to a solar cell structure or solar cell piece. Processing station 1050 may include a second alignment unit for aligning the adhesive application unit and the solar cell structure or piece relative to each other, as described herein.

Processing station 1060 shown in FIG. 14 may be a cleaving station. Processing station 1060 may include a cleaving unit.

An apparatus as described herein may include a cleaving unit for separating a solar cell structure into a plurality of solar cell pieces, or shingles. For example, a cleaving unit can be configured for cleaving the solar cell structure, particularly by applying an upward force to the solar cell structure. The apparatus may be configured such that, during the cleaving of a solar cell structure, the second side of the solar cell structure faces upward. The second side of the solar cell structure can be the front side of the solar cell structure.

Processing station 1070 shown in FIG. 14 may be an assembly station. Processing station 1070 may include an assembling unit.

An apparatus, as described herein, may include an assembling unit configured for assembling a solar cell arrangement comprising a plurality of partially overlapping solar cell pieces. A solar cell arrangement may also be referred to as a shingled solar cell arrangement. The apparatus may be configured such that, during the connecting of the plurality of solar cell pieces to each other, the respective front sides of the solar cell pieces face upward.

Processing station 1080 shown in FIG. 14 may be a curing station. Processing station 1080 may include a curing unit.

An apparatus, as described herein, may include a curing unit. The curing unit may be configured for curing the solar cell arrangement of partially overlapping solar cell pieces. The apparatus may be configured such that, during the curing of a solar cell arrangement, the sunny side of the solar cell arrangement faces upward. A curing unit may include a heating device. A heating device can be selected from the group consisting of conduction heaters (e.g., hot plates), convective heaters, resistive heaters, infrared heaters, lamp heaters, hot air heaters, and any combination thereof.

According to embodiments described herein, an adhesive may be provided on a solar cell structure. When the adhesive is provided on the solar cell structure, the solar cell structure may be a complete, i.e. unseparated, solar cell structure. The adhesive may be provided on the solar cell structure before separating the solar cell structure in solar cell pieces. Alternatively, according to embodiments, the adhesive may be provided on a solar cell piece. The solar cell piece may be obtained by separating a solar cell structure in solar cell pieces, e.g. by cleaving or laser singulating the solar cell structure. The adhesive may provided on the solar cell piece after separating the solar cell structure into two or more solar cell pieces.

According to a further embodiment, a method is provided. The method includes providing a solar cell structure having a first side and a second side. The method includes directing a laser beam onto the first side of the solar cell structure to scribe the solar cell structure or to cut through the solar cell structure. The method includes separating the solar cell structure into two or more solar cell pieces, the two or more solar cell pieces comprising at least a first solar cell piece, the first solar cell piece having a first side and a second side. The method includes providing a first adhesive on the second side of the first solar cell piece.

Embodiments described herein provide for a method in which the adhesive is provided on an individual solar cell piece, or solar cell shingle, i.e. after separating the solar cell structure into solar cell pieces. The adhesive is provided on the second side of the first solar cell piece, e.g. the front side of the first solar cell piece. The adhesive is provided on a side which is opposite to the first side of the solar cell structure, i.e. the side on which the laser beam impinges for scribing the solar cell structure or cutting through the solar cell structure. In light thereof, contamination of the adhesive can be reduced or even prevented.

For example, the method may include a first operation, a second operation after the first operation, a third operation after the second operation and a fourth operation after the third operation. The first operation may include scribing a solar cell structure on the back side of the solar cell structure. During the scribing, the back side of the solar cell structure may face upward. The second operation may include flipping the solar cell structure so that, directly after the flipping, the front side of the solar cell structure faces upward. The third operation may include cleaving the solar cell structure to separate the solar cell structure into two or more solar cell pieces. During the cleaving, the front side of the solar cell structure may face upward. The fourth operation may include printing an adhesive on each of the two or more solar cell pieces. During the printing, the front sides of the two or more solar cell pieces may face upward.

In another example, the method may include a first operation, a second operation after the first operation and a third operation after the second operation. The first operation may include performing laser singulation of a solar cell structure, wherein a laser beam impinging on the back side of the solar cell structure is configured for cutting though the solar cell structure to separate the solar cell structure into solar cell pieces. During the laser singulation, the back side of the solar cell structure may face upward. The second operation may include flipping the solar cell pieces so that, directly after the flipping, the respective front sides of the solar cell pieces face upward. The third operation may include printing an adhesive on each of the solar cell pieces. During the printing, the front sides of the two or more solar cell pieces may face upward.

In some implementations, the separation of the solar cell structure into two or more solar cell pieces may be an additional operation of the method performed after directing the laser beam onto the first side of the solar cell structure. For example, separating the solar cell structure into two or more solar cell pieces may include cleaving the solar cell structure. The cleaving may be performed after scribing the solar cell structure. In other implementations, the separation of the solar cell structure into two or more solar cell pieces may be provided by the laser beam cutting through the solar cell structure. No additional cleaving operation may be necessary.

As described herein, a solar cell structure has a first side 12 and a second side 14. A solar cell piece can be obtained by separating the solar cell structure in solar cell pieces. The solar cell piece is a segment of the original solar cell structure. The solar cell piece has a first side and a second side, e.g. first side 12a and second side 14a of solar cell piece 10a shown in FIG. 6. The first side of the solar cell piece corresponds to the first side of the original solar cell structure. The second side of the solar cell piece corresponds to the second side of the original solar cell structure. For example, the solar cell piece may include a photovoltaic area being a portion of a larger photovoltaic area of the original solar cell structure. The photovoltaic area of the original solar cell structure may define the second side of the solar cell structure. The photovoltaic area of the solar cell piece may define the second side of the solar cell piece.

A solar cell piece, e.g. the first solar cell piece as described herein, may have a front side and a back side. The front side of the solar cell piece may be configured for receiving electromagnetic radiation. The electromagnetic radiation may be converted into electrical power by the solar cell piece. The back side of the solar cell piece may be opposite to the front side. The first side of a solar cell piece may be the back side of the solar cell piece. The second side of the solar cell piece may be the front side of the solar cell piece.

During the directing of a laser beam onto the first side of a solar cell structure to scribe the solar cell structure or to cut through the solar cell structure, the first side of the solar cell structure may face upward. The laser beam incident on the first side of the solar cell structure may be incident on the solar cell structure from above the solar cell structure. Alternatively, during the directing of a laser beam onto the first side of a solar cell structure to scribe the solar cell structure or to cut through the solar cell structure, the first side of the solar cell structure may face downward.

Providing a first adhesive on the second side of the first solar cell piece, as described herein, may include printing the first adhesive on the second side of the first solar cell piece.

During the providing of the first adhesive on the second side of the first solar cell piece, the second side of the first solar cell piece may face upward. The adhesive may be provided on the first solar cell piece in a sunny-up configuration of the solar cell piece.

A solar cell piece, e.g. the first solar cell piece as described herein, may include a conductive structure or a conductive pattern, particularly a conductive line pattern. A conductive pattern or structure can include a bus bar and/or a plurality of fingers. The solar cell piece can include a conductive pattern or structure on the front side of the solar cell piece. Additionally or alternatively, the solar cell piece can include a conductive pattern or structure on the back side of the solar cell piece. For example, the solar cell piece can include a first conductive pattern including a single bus bar and a plurality of fingers on the front side of the solar cell piece. The solar cell piece can include a second conductive pattern including a further bus bar on the back side of the solar cell piece.

Providing an adhesive on a solar cell piece can include providing the adhesive on at least a portion of a conductive structure or pattern of the solar cell piece, particularly a conductive pattern on the front side of the solar cell piece. Providing the adhesive on the solar cell piece may include providing the adhesive on a bus bar of the solar cell piece. The adhesive may be provided on a bus bar, wherein the bus bar is provided on a photovoltaic area of the solar cell piece.

During the providing the adhesive on a solar cell piece, the solar cell piece may be in a substantially horizontal orientation.

In some implementations, the method may include turning over a solar cell structure or the first solar cell piece, e.g. after directing a laser beam onto the first side of the solar cell structure and/or before providing the first adhesive on the second side of the first solar cell piece. In some implementations, the method may include turning over the solar cell structure after directing the laser beam onto the first side of the solar cell structure to scribe the solar cell structure and/or before cleaving the solar cell structure. In other implementations, the method may include turning over the first solar cell piece after directing the laser beam onto the first side of the solar cell structure to cut through the solar cell structure.

A method, as described, herein, may include aligning a solar cell structure and a laser unit relative to each other. A laser unit may be configured for at least one of scribing the solar cell structure and cutting through the solar cell structure. The aligning may be based on a position of at least a portion of a first conductive structure of the solar cell structure.

A method, as described, herein, may include aligning a solar cell structure or solar cell piece and an adhesive application unit relative to each other, wherein the adhesive is provided by the adhesive application unit. The aligning may be based on a position of at least a portion of a second conductive structure of the solar cell structure or solar cell piece.

A method as described herein may include separating a solar cell structure into two or more solar cell pieces, the two or more solar cell pieces comprising at least a first solar cell piece. The two or more solar cell pieces may include a second solar cell piece. The second solar cell piece may have a first side and a second side. The first side of the second solar cell piece may be the back side of the second solar cell piece. The second side of the second solar cell piece may be the front side of the second solar cell piece. The method may include providing a second adhesive on the second side of the second solar cell piece.

A method, as described, herein, may include assembling a solar cell arrangement including a plurality of partially overlapping solar cell pieces, the solar cell arrangement including the first solar cell piece as described herein. The method may include curing the solar cell arrangement.

According to a further embodiment, an apparatus is provided. The apparatus includes a support system as described herein. The support system includes one or more support units for supporting a solar cell structure. The apparatus includes a laser unit as described herein. The laser unit is configured for at least one of scribing the solar cell structure and cutting through the solar cell structure. The apparatus includes a separation device configured for separating the solar cell structure in two or more solar cell pieces, the two or more solar cell pieces comprising at least a first solar cell piece. The separation device includes at least one of the laser unit and a cleaving unit as described herein. The cleaving unit is configured for applying a force to the solar cell structure. The apparatus includes an adhesive application unit as described herein. The apparatus is configured for directing a laser beam onto a first side of the solar cell structure to scribe the solar cell structure or to cut through the solar cell structure. The apparatus is configured for providing a first adhesive on a second side of the first solar cell piece.

The adhesive application unit may include an adhesive printing unit as described herein. The adhesive printing unit may be configured for printing the first adhesive on the first solar cell piece. The apparatus may include a first alignment unit as described herein. The first alignment unit may be configured for aligning the solar cell structure and the laser unit relative to each other. The apparatus may include a second alignment unit as described herein. The second alignment unit may be configured for aligning the first solar cell piece and the adhesive application unit relative to each other.

While the foregoing is directed to embodiments of the disclosure, other and further embodiments of the disclosure may be devised without departing from the basic scope thereof, and the scope thereof is determined by the claims that follow.

1. A method for processing a solar cell structure, the method comprising:
providing a solar cell structure having a first side and a second side;
at least one of (a) scribing the solar cell structure on the first side of the solar cell structure and (b) cutting through the solar cell structure using a laser beam incident on the first side of the solar cell structure; and
providing an adhesive on the second side of the solar cell structure.

2. The method of claim 1, wherein the solar cell structure has a front side, wherein the second side of the solar cell structure is the front side of the solar cell structure.

3. The method of claim 1, wherein during the providing the adhesive, the second side of the solar cell structure faces upward.

4. The method of claim 1, the method further comprising:
turning over the solar cell structure from a first position into a second position, wherein in the first position the first side of the solar cell structure faces upward, and in the second position the second side of the solar cell structure faces upward.

5. The method of claim 1, wherein the providing the adhesive comprises printing the adhesive on the second side of the solar cell structure.

6. The method of claim 1, further comprising at least one of the following:
aligning the solar cell structure and a laser unit relative to each other, wherein the laser unit is configured for at least one of the scribing the solar cell structure and the cutting through the solar cell structure, wherein the aligning is based on a position of at least a portion of a first conductive structure of the solar cell structure; and
aligning the solar cell structure and an adhesive application unit relative to each other, wherein the adhesive is provided by the adhesive application unit, wherein the aligning is based on a position of at least a portion of a second conductive structure of the solar cell structure.

7. A method for manufacturing a shingled solar cell arrangement:
performing the method for processing a solar cell structure according to claim 1;
separating the solar cell structure into a plurality of solar cell pieces, the plurality of solar cell pieces comprising a first solar cell piece;
assembling a solar cell arrangement comprising a plurality of overlapping solar cell pieces, the solar cell arrangement comprising the first solar cell piece.

8. An apparatus for processing a solar cell structure, the solar cell structure having a first side and a second side, the apparatus comprising:
a support system including one or more support units for supporting the solar cell structure;
a laser unit configured for at least one of scribing the solar cell structure supported by the support system and cutting through the solar cell structure supported by the support system; and
an adhesive application unit configured for providing an adhesive on the solar cell structure supported by the support system;
wherein the apparatus is configured for at least one of (a) scribing the solar cell structure on the first side of the solar cell structure and (b) cutting through the solar cell structure using a laser beam incident on the first side of the solar cell structure, and
wherein the apparatus is configured for providing the adhesive on the second side of the solar cell structure.

9. The apparatus of claim 8, wherein the solar cell structure has a front side, wherein the second side of the solar cell structure is the front side of the solar cell structure.

10. An apparatus, comprising:
a support system configured for supporting a solar cell structure;
a laser unit configured for at least one of scribing the solar cell structure and cutting through the solar cell structure;
an adhesive application unit configured for providing an adhesive on the solar cell structure;
a flipping unit configured for turning over the solar cell structure; and
an assembling unit configured for assembling a solar cell arrangement comprising a plurality of partially overlapping solar cell pieces.

11. The apparatus of claim 10, wherein the adhesive application unit includes an adhesive printing unit configured for printing the adhesive on the solar cell structure.

12. The apparatus of claim 10, the apparatus further comprising:
a cleaving unit for cleaving the solar cell structure by applying an upward force to the solar cell structure.

13. A method, comprising:
providing a solar cell structure having a first side and a second side;
directing a laser beam onto the first side of the solar cell structure to scribe the solar cell structure or to cut through the solar cell structure;
separating the solar cell structure into two or more solar cell pieces, the two or more solar cell pieces comprising at least a first solar cell piece, the first solar cell piece having a first side and a second side; and
providing a first adhesive on the second side of the first solar cell piece.

14. An apparatus, comprising;
a support system comprising one or more support units for supporting a solar cell structure;
a laser unit configured for at least one of scribing the solar cell structure and cutting through the solar cell structure;
a separation device configured for separating the solar cell structure in two or more solar cell pieces, the two or more solar cell pieces comprising at least a first solar cell piece, the separation device comprising at least one of the laser unit and a cleaving unit configured for applying a force to the solar cell structure; and
an adhesive application unit,
wherein the apparatus is configured for directing a laser beam onto a first side of the solar cell structure to scribe the solar cell structure or to cut through the solar cell structure, and
wherein the apparatus is configured for providing a first adhesive on a second side of the first solar cell piece.

15. The apparatus of claim 14, wherein the first side of the solar cell structure is a back side of the solar cell structure and the second side of the first solar cell piece is a front side of the first solar cell piece.

16. A method for manufacturing a shingled solar cell arrangement, comprising:
performing the method for processing a solar cell structure according to claim 13;
separating the solar cell structure into a plurality of solar cell pieces, the plurality of solar cell pieces comprising a first solar cell piece; and
assembling a solar cell arrangement comprising a plurality of overlapping solar cell pieces, the solar cell arrangement comprising the first solar cell piece.

17. The apparatus of claim 8, further comprising at least one of:
a first alignment unit for aligning the solar cell structure and the laser unit relative to each other; and
a second alignment unit for aligning the solar cell structure and the adhesive application unit relative to each other.

18. The method of claim 16, wherein the first side of the solar cell structure is a back side of the solar cell structure and the second side of the first solar cell piece is a front side of the first solar cell piece.

19. A method for manufacturing a shingled solar cell arrangement, comprising:
performing the method of claim 16: and
assembling a solar cell arrangement comprising a plurality of overlapping solar cell pieces, the solar cell arrangement comprising the first solar cell piece.

20. The apparatus of claim 13, the apparatus further comprising:
a cleaving unit for cleaving the solar cell structure by applying an upward force to the solar cell structure.
